(19) United States
(12) Patent Application Publication
(10) Pub. No.: US 2007/0285686 A1
(43) Pub. Date: Dec. 13, 2007

(54) Image forming apparatus and image forming method

(75) Inventor: Masashi Honda, Tagata-gun (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignees: Kabushiki Kaisha Toshiba, Minato-ku (JP); Toshiba Tec Kabushiki Kaisha, Shinagawa-ku (JP)

(21) Appl. No.: 11/452,044

(22) Filed: Jun. 13, 2006

(51) Int. Cl. G03F 3/08

(52) U.S. Cl. 358/1.9; 358/518

(57) ABSTRACT

An image forming apparatus of the invention is a tandem type image forming apparatus for forming a color image and includes a bit-length converting unit configured to convert a plurality of first image data having a first bit length and provided for respective print colors into a plurality of second image data having a second bit length smaller than the first bit length in at least one of the print colors, a plurality of storage units configured to temporarily store the second image data for the respective print colors and to be capable of setting delay amounts different for the respective print colors to the second image data, a plurality of photoreceptors provided for the respective print colors and arranged at specified intervals. According to the invention, the quality of an image is kept at a specific level, and the capacity of a memory for delay adjustment of an image forming signal to each photoreceptor can be reduced.

### BACKGROUND OF THE INVENTION

1. Technical Field of the Invention

The present invention relates to an image forming apparatus and an image forming method, and particularly to an image forming apparatus capable of performing color printing and an image forming method.

2. Related Art

In an image forming apparatus such as a color copying machine or a color printer, a plurality of print colors such as cyan (C), magenta (M), yellow (Y) and black (K) are used and a color image is printed on a recording sheet or the like.

In order to keep the gradation reproducibility and color reproducibility of a color image at a high level, it is necessary that an image signal (hereinafter referred to as a print color signal) corresponding to each print color is made multi-bit multi-gradation data, for example, a 8-bit 256-gradation signal.

On the other hand, recently, the resolution of image data has been rapidly increased, and it is necessary that an image forming apparatus processes a large number of pixel signals. Thus, the capacity of a memory to temporarily store print color signals in various digital processings has also been rapidly increased, which has become a factor of increasing the cost of the image forming apparatus.

In order to deal with this, techniques for the purpose of reducing the memory capacity have been conventionally studied. For example, JP 2002-207335 A1 discloses a technique in which three-color print color signals C, M and Y are classified into three categories of main density, sub density 1 and sub density 2 according to the degree of influence on picture quality, and the signal classified as the main density is made to remain 8 bits, whereas the signal classified as the sub density 1 is converted from 8 bits to 5 bits, and the signal classified as the sub density 2 is changed from 8 bits to 4 bits, and therefore, the total number of signal bits is reduced, and the memory capacity can also be decreased.

The processing to temporarily store the print color signals is performed in a plurality of parts in the image forming apparatus, and the required storage capacity of the memory varies according to the processing content to be stored.

Among image forming apparatuses, an image forming apparatus called a tandem type has a configuration in which for example, four photoconductive drums corresponding to four print colors of Y, M, C and K are provided. The four photoconductive drums are arranged at almost equal intervals in the order of, for example, Y, M, C and K. While a recording sheet passes over the four photoconductive drums sequentially, four-color developed images are transferred onto the recording sheet from the respective photoconductive drums so as to be sequentially superimposed, and the color image is formed on the recording sheet. It takes a specified movement time for the recording sheet to move from a transfer position of a photoconductive drum, for example, the photoconductive drum for Y to a transfer position of the adjacent photoconductive drum for M.

In general, a physical positional relation between a laser oscillator to irradiate the photoconductive drum and the photoconductive drum is common to the respective colors, and the rotation speed of the photoconductive drum is the same for the respective colors. Accordingly, in order to transfer the Y image and the M image to the same position of the recording sheet, it is necessary that the output timing of the image forming signal to the photoconductive drum for M is delayed from the output timing of the image forming signal to the photoconductive drum for Y by the movement time of the recording sheet. That is, it is necessary that the timing of the drive signal of the laser oscillator for M (hereinafter simply referred to as the signal for M) is delayed from the signal for Y by the movement time “T”.

From a similar view point, it is necessary that the signal for C is delayed from the signal for Y by “2T”, and the signal for K is delayed from the signal for Y by “3T”.

A configuration is effective in which these delays are realized by using memories at a stage of digital signals before the signal for M to the signal for K are converted into analog signals, and the configuration is normally adopted.

However, the capacity of the memories for delay depends on the pixel density, and has become the capacity which can not be neglected in the recent high density image. Thus, a demand for reduction in the capacity of the memory for delay has been raised.

### SUMMARY OF THE INVENTION

The invention has been made in view of the above circumstances, and it is an object to provide an image forming apparatus and an image forming method in which in a tandem type image forming apparatus and an image forming method, the quality of an image is kept at a specific level, and the capacity of a memory for delay adjustment of an image forming signal to each photoreceptor can be reduced.

In order to achieve the above object, the image forming apparatus according to an aspect of the invention is a tandem type image forming apparatus for forming a color image and is characterized by including a bit-length converting unit configured to convert a plurality of first image data having a first bit length and provided for respective print colors into a plurality of second image data having a second bit length smaller than the first bit length in at least one of the print colors, a plurality of storage units configured to temporarily store the second image data for the respective print colors and to be capable of setting delay amounts different for the respective print colors to the second image data, a plurality of photoreceptors provided for the respective print colors and arranged at specified intervals, and a transfer unit configured to move an image bearing body along the plurality of photoreceptors and to superimpose and transfer the print colors onto the image bearing body.

Besides, in order to achieve the above object, the image forming method according to another aspect of the invention is an image forming method for forming a color image by a tandem type image forming apparatus and is characterized by including a bit-length converting step of converting a plurality of first image data having a first bit length and provided for respective print colors into a plurality of second image data having a second bit length smaller than the first bit length in at least one of the print colors, a step of temporarily storing the second image data for the respective print colors and setting delay amounts different for the respective print colors to the second image data, a step of exposing a plurality of photoreceptors provided for the respective print colors and arranged at specified intervals, and a transfer step of moving an image bearing body along the plurality of photoreceptors and superimposing and transferring the print colors onto the image bearing body.

### BRIEF DESCRIPTION OF THE DRAWINGS

In the accompanying drawings,

FIG. 1 is a view showing an example of a whole configuration of an image forming apparatus of an embodiment of the invention,

FIG. 2 is a block diagram showing an example of a functional configuration of the image forming apparatus of the embodiment of the invention,

FIG. 3 is a view showing an example of a configuration of a print unit in the image forming apparatus of the embodiment of the invention,

FIG. 4 is a view showing an example of a detail configuration of a generally used print unit for comparison with the embodiment of the invention,

FIG. 5A to FIG. 5C are views showing the operation concept of position control bits,

FIG. 6 is a view showing an example of a detail configuration of a print unit in the image forming apparatus of the embodiment of the invention,

FIG. 7A and FIG. 7B are views showing examples of a gradation bit number and the degree of a gradation change of a gradation image, and

FIG. 8A and FIG. 8B are views for explaining the concept of a selection method of a gradation bit number according to the embodiment.

### DETAILED DESCRIPTION OF THE PREFERRED EMBODIMENTS

Embodiments of an image forming apparatus and an image forming method of the invention will be described with reference to the accompanying drawings.

### (1) Configuration of image forming apparatus

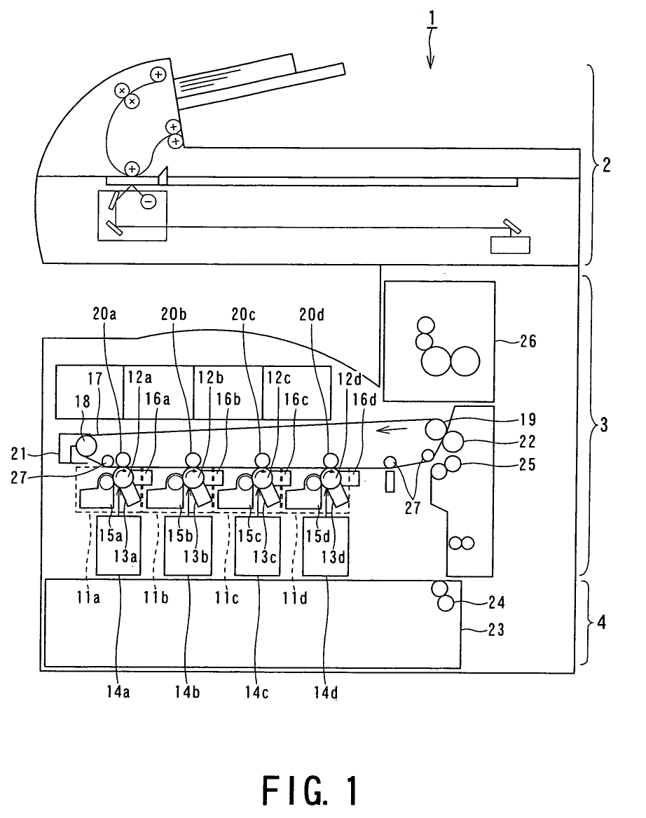

FIG. 1 is a view showing an example of a configuration of a tandem type image forming apparatus 1 of an embodiment of the invention. As shown in FIG. 1, the image forming apparatus 1 includes a scanner unit 2, an image forming unit 3, and a paper feed unit 4.

The scanner unit 2 irradiates a light to a document set on a document table, guides a reflected light from the document through a plurality of optical members to a light receiving element, performs photoelectric conversion, and supplies an image signal to the image forming unit 3.

The image forming unit 3 is provided with four process cartridges 11a, 11b, 11c and 11d. The process cartridges 11a, 11b, 11c and 11d correspond to yellow (Y), magenta (M), cyan (C) and black (K), and respectively include photoconductive drums (photoreceptors) 12a, 12b, 12c and 12d. An image (toner image) of a developer such as toner is formed on these photoconductive drums.

The photoconductive drum 12a has, for example, a cylindrical shape with a diameter of about 30 mm, and is provided rotatably in an arrow direction in the drawing. Attached devices are disposed around the photoconductive drum 12a along the rotation direction. First, as an attached device, a charging charger 13a is provided to be opposite to the surface of the photoconductive drum 12a. The charging charger 13a uniformly negatively (−) charges the photoconductive drum 12a. An exposure device 14a to expose the charged photoconductive drum 12a to form an electrostatic latent image is provided at the downstream side of the charging charger 13a. The exposure device 14a uses a laser beam optically modulated correspondingly to the image signal supplied from the scanner unit 2 and exposes the photoconductive drum 12a. Incidentally, the exposure device 14a may use an LED (Light Emitting Diode) instead of the laser beam.

A developing unit 15a to reversal-develop the electrostatic latent image formed by the exposure device 14a is provided at the further downstream side of the exposure device 14a. An yellow (Y) developer is contained in the developing unit 15a.

An intermediate transfer belt 17 (image bearing body) as an intermediate transfer body and as one of image bearing bodies is disposed at the downstream side of the developing unit 15a so as to come in contact with the photoconductive drum 12a.

In a direction (depth direction in the drawing) orthogonal to the transport direction, the intermediate transfer belt 17 has a length (width) almost equal to the length of the photoconductive drum 12a in an axial direction. The intermediate transfer belt 17 has an endless (seamless) belt shape, is stretched over a drive roller 18 to rotate the belt at a specified speed and a secondary transfer opposite roller 19 as a driven roller, and is supported. Incidentally, a tension roller 27 to hold the intermediate transfer belt 17 at a specific tension is provided at the downstream side of the drive roller 18.

The intermediate transfer belt 17 is formed of polyimide in which carbon is uniformly dispersed and which has a thickness of, for example, 100 μm. The intermediate transfer belt 17 has an electric resistance of, for example, about 10⁻⁹ Ωcm, and exhibits semiconductivity. As a material of the intermediate transfer belt 17, any material may be used as long as it exhibits the semiconductivity in which a volume resistance value is 10⁻⁸ to 10⁻¹¹ Ωcm. For example, in addition to polyimide in which carbon is dispersed, what is obtained by dispersing conductive particles of carbon or the like into polyethylene terephthalate, polycarbonate, polytetrafluoroethylene or polyvinylidene fluoride may be used. A polymeric film may be used in which the conductive particles are not used and the electric resistance is adjusted by composition adjustment. Further, what is obtained by mixing an ion conductive material in such a polymeric film, or a rubber material, such as silicone rubber or urethane rubber, having a relatively low electric resistance may be used.

A toner cleaner (cleaning device) 16a is provided at the further downstream side of a contact position between the photoconductive drum 12a and the intermediate transfer belt 17. The toner cleaner 16a removes the residual toner on the photoreceptor after transfer by a cleaning blade.

The process cartridges 11b, 11c and 11d, in addition to the process cartridge 11a, are sequentially disposed between the drive roller 18 and the secondary transfer opposite roller 19 along the transport direction of the intermediate transfer belt 17. Each of the process cartridges 11b, 11c and 11d has the same configuration as the process cartridge 11a.

That is, the photoconductive drums 12b, 12c and 12d are provided substantially at the centers of the respective process cartridges. Besides, charging chargers 13b, 13c and 13d are respectively provided to be opposite to the surfaces of the photoconductive drums 12b, 12c and 12d. Exposure devices 14b, 14c and 14d to expose the charged photoconductive drums 12b, 12c and 12d to form electrostatic latent images are provided at the downstream side of the charging chargers 13b, 13c and 13d. Developing units 15b, 15c and 15d to reversal-develop the electrostatic latent images formed by the exposure devices 14b, 14c and 14d are provided at the further downstream side of the exposure devices 14b, 14c and 14d. Toner cleaners 16b, 16c and 16d are provided at the downstream side of contact positions between the intermediate transfer belt 17 and the photoconductive drums 12b, 12c and 12d. Incidentally, a developer of magenta (M), a developer of cyan (C) and a developer of black (K) are respectively contained in the developing units 15b, 15c and 15d.

The intermediate transfer belt 17 sequentially comes in contact with the respective photoconductive drums (photoreceptors 12a to 12d). Primary transfer rollers 20a, 20b, 20c and 20d are provided correspondingly to the respective photoconductive drums and in the vicinities of the contact positions between the intermediate transfer belt 17 and the respective photoconductive drums. That is, the primary transfer rollers 20a to 20d are provided to come in back contact with the intermediate transfer belt 17 above the corresponding photoconductive drums, and are opposite to the process cartridges 11a to 11d through the intermediate transfer belt 17. The primary transfer rollers 20a to 20d are connected to a not-shown positive (+) DC power source as voltage application means. By the positive (+) applied voltage, the toner images formed on the surfaces of the respective photoconductive drums 12a to 12d are transferred to the intermediate transfer belt 17.

An intermediate transfer belt cleaner (toner cleaner: cleaning device) 21 to remove the residual toner on the intermediate transfer belt and to receive it is provided in the vicinity of the drive roller 18 to drive the intermediate transfer belt 17.

On the other hand, a paper feed cassette 23 of the paper feed unit 4 to contain sheets (transfer member) is provided at the lower part of the image forming unit 3. A pickup roller 24 to pick up the sheets one by one from the paper feed cassette 23 is further provided in the paper feed unit 4. A resist roller pair 25 is rotatably provided in the vicinity of a secondary transfer roller 22 of the image forming unit 3. The resist roller pair 25 supplies the sheet at a specified timing to the secondary transfer roller 22 and the secondary transfer opposite roller 19 (secondary transfer unit) opposite to each other through the intermediate transfer belt 17.

Besides, a fixing unit 26 to fix the developer onto the sheet is provided above the intermediate transfer belt 17. The fixing unit 26 applies specified heat and pressure to the sheet holding the toner image and fixes the melted toner image onto the sheet.

### (2) Functional configuration of the image forming unit

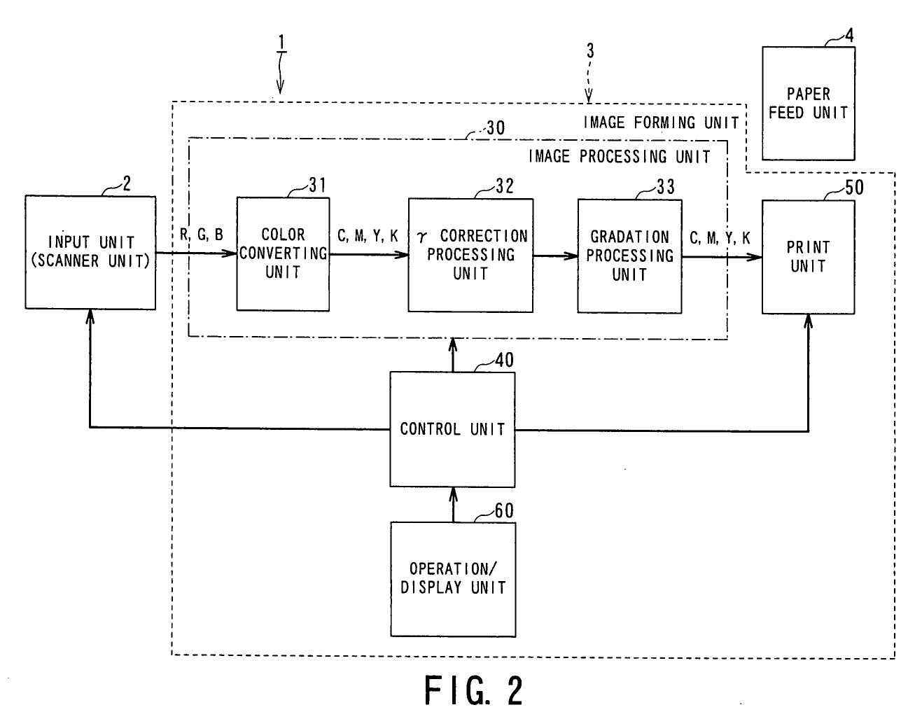

FIG. 2 is a block diagram showing an example of a functional configuration of the image forming unit 3.

The image forming unit 3 includes an image processing unit 30, a control unit 40, a print unit 50, and an operation/display unit 60.

The image processing unit 30 further includes therein a color converting unit 31 to convert three primary color data of R, G and B inputted from the scanner unit (input unit) 2 into four-color print color data Y, M, C and K, a γ correction processing unit 32 to perform a gradation correction, and a gradation processing unit 33 to perform a screen tone processing for printing or the like.

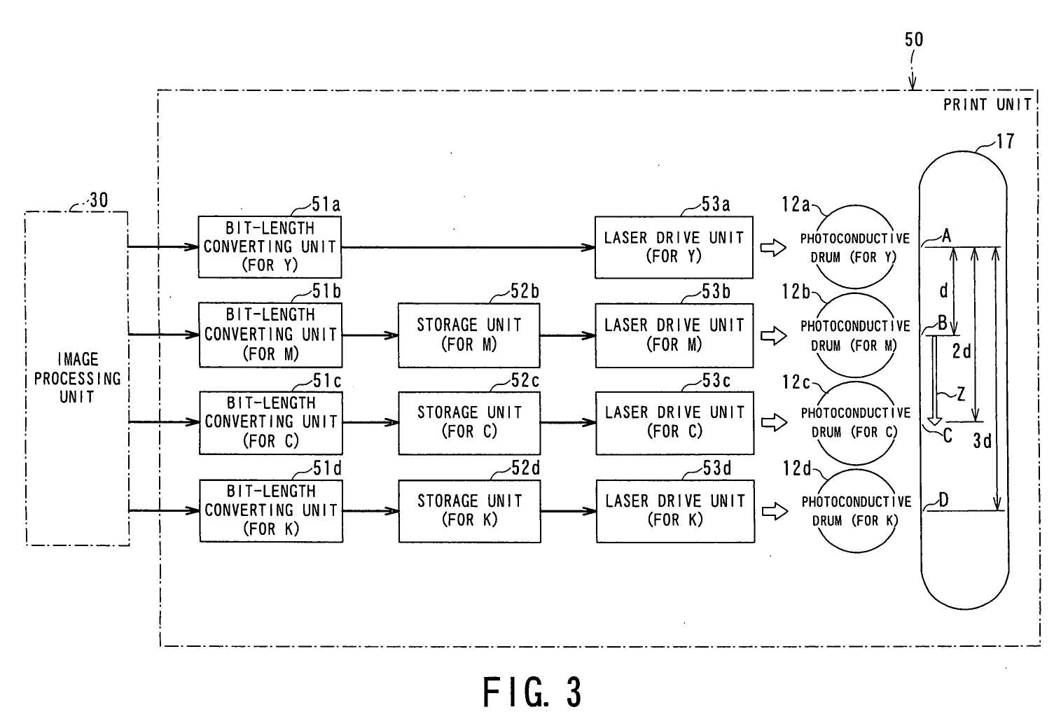

FIG. 3 is a view showing an example of a detail configuration of the print unit 50. The print unit 50 includes bit-length converting units 51a, 51b, 51c and 51d to convert at least one of print color data Y, M, C and K (hereinafter sometimes referred to as Y data, M data, C data and K data) inputted from the image processing unit 30 to obtain a bit length smaller than an input bit length.

The bit-length converting units 51a, 51b, 51c and 51d perform a control of a memory in the case where the memory (storage unit) is connected to a next stage, and are constructed of, for example, an IC such as an ASIC (Application Specific Integrated Circuit).

The Y data, M data, C data and K data are simultaneously inputted to the bit-length converting units 51a, 51b, 51c and 51d.

Among these, the Y data is directly inputted from the bit-length converting unit (for Y) 51a to a laser drive unit (for Y) 53a without an intervening storage unit.

On the other hand, the M data, C data and K data are respectively inputted to a laser drive unit (for M) 53b, a laser drive unit (for C) 53c and a laser drive unit (for K) 53d through a storage unit (for M) 52b, a storage unit (for C) 52c and a storage unit (for K) 52d.

The respective laser drive units 53a, 53b, 53c and 53d generate, for example, pulse width modulation signals according to the magnitudes of the inputted Y data, M data, C data and K data, and drive lasers based on the signals to generate laser beams. The laser beams are irradiated to the respective photoconductive drums 12a, 12b, 12c and 12d, and electrostatic latent images are formed on the surfaces of the respective photoconductive drums 12a, 12b, 12c and 12d. The electrostatic latent images are toner-developed by the developing units 15a, 15b, 15c and 15d, and become respective development images of Y, M, C and K. These development images are intermediately transferred onto the intermediate transfer belt 17.

Here, the storage unit (for M) 52b, the storage unit (for C) 52c and the storage unit (for K) 52d are provided in order to suitably set delay amounts relative to the Y data, with reference to the Y data.

As shown at the right part of FIG. 3, the intermediate transfer belt 17 is moved in the direction of an arrow Z. Thus, the intermediate transfer belt 17 is moved by a movement distance d from a contact position A between the photoconductive drum (for Y) and the intermediate transfer belt 17 to a contact position B between the photoconductive drum (for M) and the intermediate transfer belt 17. The function of the storage unit (for M) 52b is to generate a delay equivalent to this movement distance d.

When there is no delay caused by the storage unit (for M) 52b, a pixel of Y and a pixel of M, which are originally the same pixel, are shifted from each other by the movement distance d and are transferred onto the intermediate transfer belt 17, and therefore, a normal image can not be formed. The functions of the storage unit (for C) 52c and the storage unit (for K) 52d are also the same.

Accordingly, when the four photoconductive drums are arranged at substantially the equal intervals d, it is necessary that a delay equivalent to the movement distance d is generated in the storage unit (for M) 52b, a delay equivalent to the movement distance 2d is generated in the storage unit (for C) 52c, and a delay equivalent to the movement distance 3d is generated in the storage unit (for K) 52d.

Thus, according to the order of movement of the intermediate transfer belt 17 (that is, in the order of the M data, C data and K data), the storage capacities (required storage capacities) required for the respective storage units 52b, 52c and 52d become large. It is necessary that pixel data not only in the movement direction (sub-scanning direction) of the intermediate transfer belt 17 but also in the direction (main scanning direction) perpendicular to this are stored in the respective storage units 52b, 52c and 52d.

Thus, the required storage capacities of the respective storage units 52b, 52c and 52d become large so that they can not be neglected. Especially, recently, the resolution of an image has been increased, the required storage capacity tends to increase more and more, and it is an important problem to reduce the storage capacity.

The required storage capacity naturally depends on not only the delay amount, but also the magnitude of data (bit length). The point of the invention is that the storage capacities of the respective storage units 52b, 52c and 52d are reduced by reducing the bit length of the data within the possible and practical range.

Incidentally, in FIG. 1 and FIG. 3, although the configuration is described in which the development images on the respective photoconductive drums are once intermediately transferred onto the intermediate transfer belt 17, in addition to this, the gist of the invention can be applied, without modification, to a configuration in which a recording sheet (image bearing body) is transported between a transport belt and respective photoconductive drums by the transport belt having a similar configuration to the intermediate transfer belt 17, and transfer is performed directly to the recording sheet.

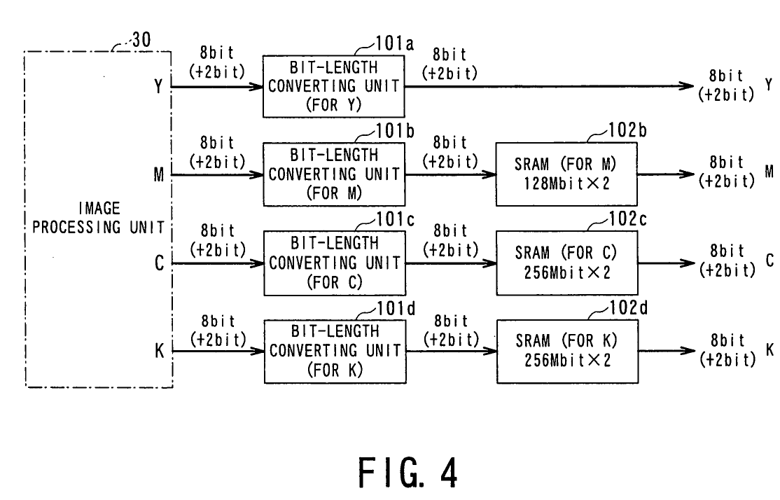

FIG. 4 shows, for reference, an example of a detail configuration of bit-length converting units 101a, 101b, 101c and 101d and storage units 102b, 102c and 102d of a general print unit for comparison with the embodiment of the invention.

Each of Y data, M data, C data and K data outputted from the image processing unit 30 includes gradation bits of 8 bits and position control bits of 2 bits. The gradation bits indicate the magnitude of each of the Y data, M data, C data and K data, and represent the data with the magnitude in the range of 0 to 255 by the gradation bits of 8 bits.

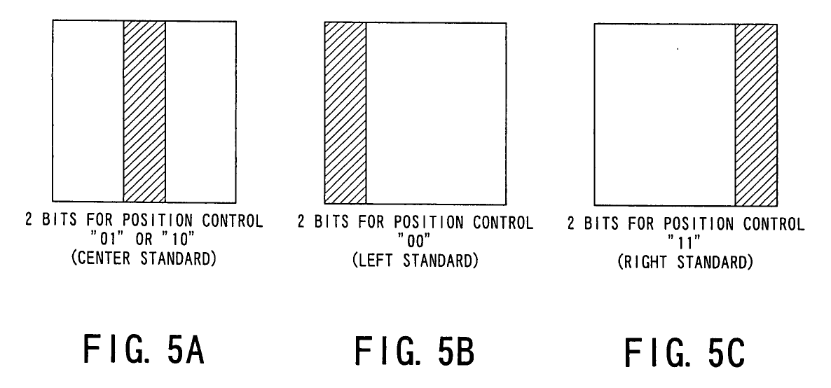

On the other hand, the position control bits (2 bits indicated in brackets in FIG. 4) are bits for adjusting the print position of each pixel to be pulse width modulated. FIG. 5A to FIG. 5C show the adjustment concept of the print position by the position control bits.

The pulse width of the laser light to be pulse width modulated is determined by the gradation bits, and in the examples of FIGS. 5A to 5C, a case is exemplified in which the pulse width of ⅕ of the maximum pulse width is determined by the gradation data. Among these, FIG. 5A is a view corresponding to a case in which the position control bits are “01” or “10”, and setting is made so that the signal of the ⅕ pulse width (signal indicated by black hatching) is positioned at the center of the pixel area shown to be substantially square.

On the other hand, in the case where the position control bits are “00”, as shown in FIG. 5B, setting is made so that the signal of the ⅕ pulse width is positioned at the left end. Besides, in the case where the position control bits are “11”, as shown in FIG. 5C, setting is made so that the signal of the ⅕ pulse width is positioned at the right end.

As stated above, the display position in the pixel area can be changed by the position control bits of 2 bits, and a contrivance is made so that a continuous and smooth image can be represented in the whole image.

Accordingly, in the case where the storage capacities of the storage units 102b, 102c and 102d are considered, it is necessary to consider the position control bits (2 bits) in addition to the gradation bits (8 bits), and the actual bit length becomes 10 bits, not 8 bits.

The general print unit (FIG. 4) has a configuration in which the Y data, M data, C data and K data outputted from the image processing unit 30 are outputted to the laser drive units 53a, 53b, 53c and 53d without changing their bit lengths. That is, in the general bit-length converting unit 101a (although the name of “bit-length converting” is given for comparison with the embodiment), an output is made to the laser drive unit (for Y) 51a without changing the input bit length, and similarly, in the bit-length converting units 101b, 101c and 101d, an output is made to the storage units (SRAM) 102b, 102c and 102d without changing the bit lengths.

As storage devices used for the storage units 102b, 102c and 102d, a semiconductor memory IC is generally used from the viewpoint of high-speed access. For example, an SRAM (Static Random Access Memory) is used.

Thus, hereinafter, there is a case where the storage units 102b, 102c and 102d are called SRAM (for M) 102b, SRAM (for C) 102c and SRAM (for K) 102d.

As set forth before, the SRAM (for M) 102b, the SRAM (for C) 102c and the SRAM (for K) 102d are used as the delay memories to correct the movement distance of the intermediate transfer belt 17, and the required storage capacities become large in the order of for the M data, for the C data and for the K data.

On the other hand, the maximum storage capacity of the semiconductor memory IC is generally provided in a unit of a multiple of 2, such as 128 Mbit, 256 Mbit or 512 Mbit.

Thus, in the general configuration shown in FIG. 4, two SRAMs each having the maximum storage capacity of 128 Mbit are used for the M data, and two SRAMs each having the maximum storage capacity of 256 Mbit are used for the C data and K data. Although the required storage capacity for the C data is smaller than the required storage capacity for the K data, since the two 128-Mbit SRAMs for the M data are insufficient, the selection of using the two SRAMs of 256 Mbit as the next large storage capacity is urged.

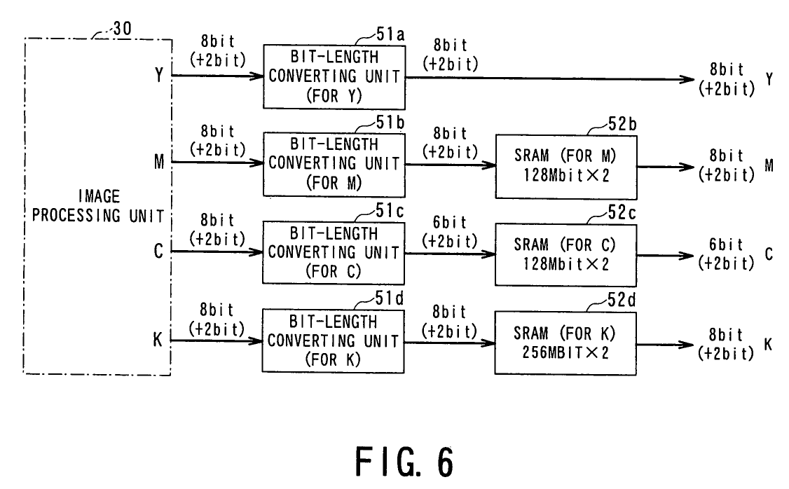

FIG. 6 is a view showing an example of a detail configuration of the bit-length converting units 51a, 51b, 51c and 51d and the SRAMs (storage unit) 52b, 52c and 52d of the print unit 50 according to the embodiment of the invention.

Different points between the embodiment and the general configuration are that in the bit-length converting unit (for C) 51c for the C data, conversion is performed to reduce the gradation bits from 8 bits to 6 bits, and the maximum storage capacity of the SRAM (for C) 52C for the C data is reduced from 256 Mbit×2 of the general configuration to 128 Mbit×2.

Although the required storage capacity is naturally reduced by reducing the number of gradation bits, the gradation of an image becomes coarse. Thus, it is necessary to previously set an allowable value (lower limit) of the gradation bits.

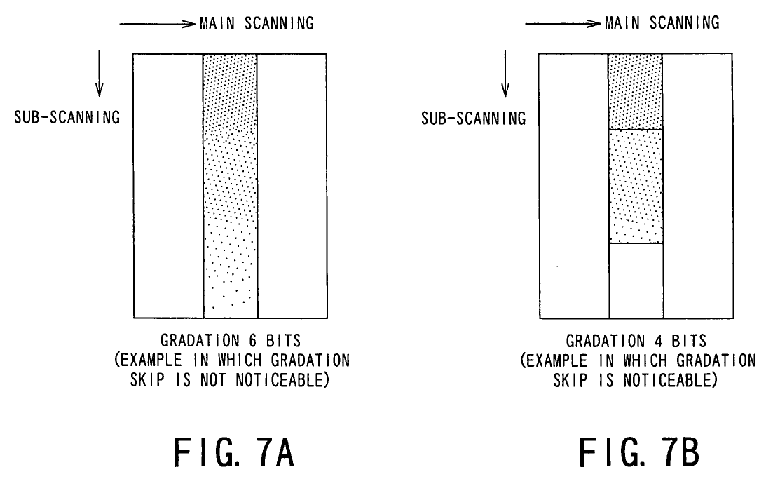

FIG. 7A is a view showing an image example in which a gradation image where density is continuously changed in a sub-scanning direction is represented with a gradation of 6 bits. On the other hand, FIG. 7B is a view showing an image example in which a similar gradation image is represented with a gradation of 4 bits.

As is understood from FIG. 7A and FIG. 7B, in the case where the gradation bit number is made 6 bits, a discrete change (“gradation skip”) is not very noticeable. On the other hand, in the case where the gradation bit number is made 4 bits, the “gradation skip” due to a change point of bits is noticeable.

From this, it is understood that the lower limit of the gradation bit number is required to be set to 5 bits or more, preferably 6 bits or more.

As set forth above, the required storage capacity of the storage unit is determined by the bit number (bit number in which two bits for position control are added to the gradation bit number) and the delay amount.

On the other hand, the maximum storage capacity of the semiconductor memory IC (SRAM) constituting the storage unit is normally a multiple of 2 such as 128 Mbit or 256 Mbit.

Accordingly, it can be said that it is a most excellent in cost-performance and realistic determination method to find such a gradation bit number that the number of the semiconductor memory ICs becomes minimum within the range where the required storage capacity is satisfied.

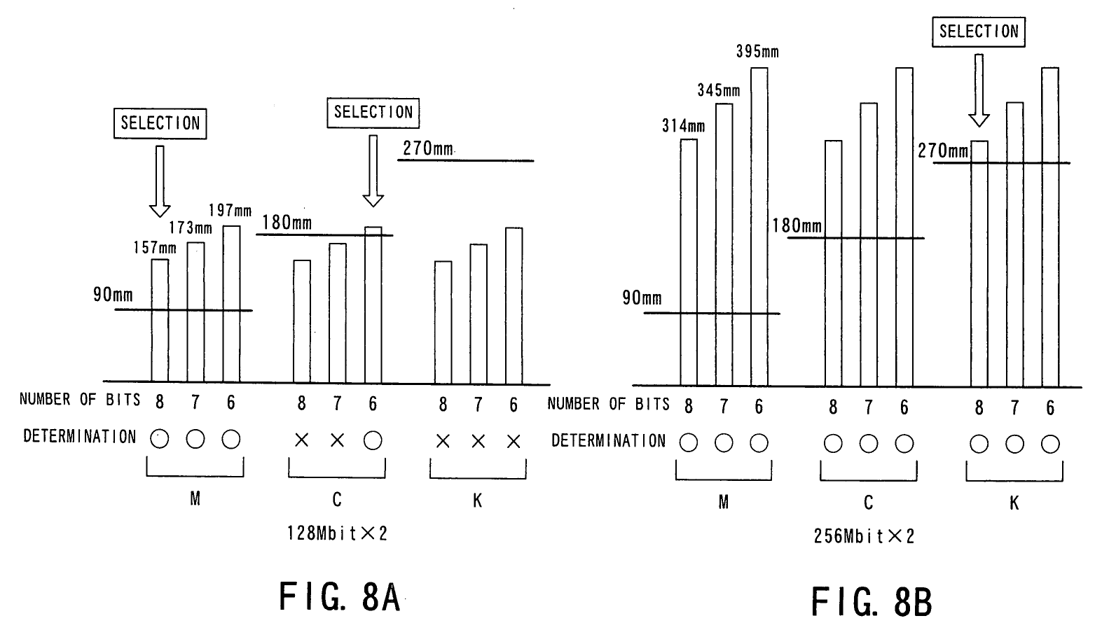

FIG. 8A and FIG. 8B are views for explaining a specific method for determining gradation bit numbers for M data, C data and K data from the above viewpoint.

FIG. 8A is a view showing a relation between the storage capacity, which can be realized when the storage unit includes two 128-Mbit SRAMs, and the required storage capacity, while the gradation bit number is made a parameter. Besides, FIG. 8B is a view showing a relation between the storage capacity, which can be realized when the storage unit includes two 256-Mbit SRAMs, and the required storage capacity, while the gradation bit number is made a parameter.

First, FIG. 8A will be described. In FIG. 8A, the storage capacity is converted into a delay distance and is displayed (the same is applied to FIG. 8B).

It is assumed that the interval d of the photoconductive drums is 90 mm. Accordingly, with respect to the Y data, in order to make the pixel position of the M data coincident with the pixel position of the Y data input, it is necessary to delay the image data by an amount equivalent to the movement of the intermediate transfer belt 17 in the interval d (90 mm). Then, the storage capacity equivalent to the movement distance of 90 mm is the storage capacity necessary for the SRAM (for M). In the group of “M” of FIG. 8A, an amount obtained by converting the required storage capacity into this movement distance is indicated by a thick bar of a horizontal line affixed with “90 mm”.

On the other hand, in the case where the gradation bits are made 8 bits (actually 10 bits since two bits for position control are added), the number of pixels stored in two 128-Mbit SRAMs can be calculated. From this number of pixels, the number of pixels in the sub-scanning direction (movement direction of the intermediate transfer belt 17) at the time when the number of pixels in the main scanning direction is made a specified number (for example, 7200 pixels) is obtained. The number of pixels in the sub-scanning direction can be converted into the distance (distance to be delayed) in the sub-scanning direction.

As a result of the conversion as stated above, in the case where the gradation bit number is set to 8 bits, the maximum delay distance which can be realized by the two 128-Mbit SRAMs is obtained. Specifically, the distance is about 157 mm indicated by the vertical bar of “M” of FIG. 8A.

Similarly, in the case where the gradation bit number is set to 7 bits, and in the case where it is set to 6 bits, when the maximum delay distances realized by the two 128-Mbit SRAMs are obtained, they become about 173 mm and about 197 mm, respectively. The magnitudes of the delay distances are indicated as the lengths of vertical bars at positions of the group of “M” of FIG. 8A.

With respect to the M data, the required delay amount is 90 mm, the maximum delay amount realized by the two 128-Mbit SRAMs is about 157 mm in the case where the gradation bits are 8 bits, about 173 mm in the case of 7 bits, and about 197 mm in the case of 6 bits, and any gradation bit number satisfies the required delay amount.

In FIGS. 8A and 8B, a circle below the vertical bar indicates “satisfied” and a cross indicates “unsatisfied”.

In this case, although the gradation bit number can be set to any bit number of 8, 7 and 6, since the maximum storage capacity of the SRAMs and the number of the SRAMs are the same, it is most excellent in cost-performance to select 8 bits, which are relatively high in gradation, as the gradation bit number.

On the other hand, in the case of the C data, the required delay amount is 180 mm. In this relation, the maximum delay amount realized by the two 128-Mbit SRAMs is the same as the maximum delay amount for the M data. Accordingly, the required delay amount 180 mm is satisfied only in the case where the gradation bits are set to 6 bits (maximum delay amount is about 197 mm).

Conventionally, since the gradation bit number is fixedly limited to 8 bits, it is determined that 157 mm as the maximum delay amount in this case does not satisfy the required delay amount 180 mm, and a configuration of not two 128-Mbit SRAMs, but two higher 256-Mbit ones is adopted.

On the other hand, in this embodiment, the gradation bit number is not fixedly limited to 8 bits, but can be flexibly selected in the allowable range of from 8 bits to 6 bits. As a result, the configuration of the storage unit for C data can be change from the configuration of the two 256-bit SRAMs to the more inexpensive configuration of the two 128-bit SRAMs.

On the other hand, in the case of the K data, the required delay amount is 270 mm. In this case, the maximum delay amount realized by the two 128-Mbit SRAMs does not satisfy the required delay amount in any of the three gradation bit numbers.

In this case, a configuration where two 256-Mbit SRAMs, the storage capacity of which is a higher rank, are used is adopted.

FIG. 8B shows delay amounts realized in the case where two 256-Mbit SRAMs are used for the respective gradation bits of 8, 7 and 6 bits, and required delay amounts (the same as those of FIG. 8A).

In the case where the two 256-Mbit SRAMs are used, the maximum delay amount of about 314 mm can be realized when the gradation bit number is 8, the maximum delay amount of about 345 mm can be realized when the gradation bit number is 7, and the maximum delay amount of about 395 mm can be realized when the gradation bit number is 6. All of these satisfy the required delay amounts.

Then, with respect to the K data, two 256-Mbit SRAMs are used, and 8 bit which is most excellent in gradation is selected as the gradation bit number.

The configuration example (FIG. 6) of the embodiment illustrated before is the illustration of the gradation bit numbers selected by the above method and the use configuration of the SRAMs.

As described above, according to the embodiment, in the tandem type image forming apparatus and the image forming method, the quality of an image is kept at a specific level, and the capacity of the memory for delay adjustment of the image forming signal to each photoreceptor can be reduced.

Incidentally, the invention is not limited to the embodiment as described, but can be embodied at a practical stage while structural elements are modified within the range not departing from the gist. Besides, various inventions can be formed by suitable combinations of a plurality of structural elements disclosed in the embodiment. For example, some structural elements may be deleted from all structural elements disclosed in the embodiment. Further, structural elements of different embodiments may be suitably combined.

What is claimed is:

1. A tandem type image forming apparatus for forming a color image, comprising:
a bit-length converting unit configured to convert a plurality of first image data having a first bit length and provided for respective print colors into a plurality of second image data having a second bit length smaller than the first bit length in at least one of the print colors;
a plurality of storage units configured to temporarily store the second image data for the respective print colors and to be capable of setting delay amounts different for the respective print colors to the second image data;
a plurality of photoreceptors provided for the respective print colors and arranged at specified intervals; and
a transfer unit configured to move an image bearing body along the plurality of photoreceptors and to superimpose and transfer the print colors onto the image bearing body.

2. The image forming apparatus according to claim 1, Wherein,
the plurality of storage units are set so that the delay amount of the print color corresponding to the photoreceptor positioned at a downstream side in a movement of the image bearing body is larger than the delay amount of the print color corresponding to the photoreceptor positioned at an upstream side, and
a storage capacity of each of the storage units is determined based on a required storage capacity obtained by the delay amount and the second bit length.

3. The image forming apparatus according to claim 2, Wherein,
each of the storage units includes a combination of a plurality of semiconductor memory ICs different in maximum storage capacity, and
the combination of the plurality of semiconductor memory ICs is a combination in which a sum of the maximum storage capacities becomes minimum within a range to satisfy the required storage capacity.

4. The image forming apparatus according to claim 1, Wherein,
the first bit length is 8 bits and the second bit length is 6 bits.

5. The image forming apparatus according to claim 3, Wherein,
the first bit length is 8 bits and the second bit length is 6 bits.

6. The image forming apparatus according to claim 1, Wherein,
the print colors are yellow, magenta, cyan and black.

7. A tandem type image forming apparatus for forming a color image, comprising:
bit-length converting means for converting a plurality of first image data having a first bit length and provided for respective print colors into a plurality of second image data having a second bit length smaller than the first bit length in at least one of the print colors;
a plurality of storage means for temporarily storing the second image data for the respective print colors and configured to be capable of setting delay amounts different for the respective print colors to the second image data;
is a plurality of photoconductive means provided for the respective print colors and arranged at specified intervals; and
transfer means for moving an image bearing body along the plurality of photoconductive means and superimposing and transferring the print colors onto the image bearing body.

8. The image forming apparatus according to claim 7, Wherein,
the plurality of storage means are set so that the delay amount of the print color corresponding to the photoreceptor positioned at a downstream side in a movement of the image bearing body is larger than the delay amount of the print color corresponding to the photoreceptor positioned at an upstream side, and
a storage capacity of each of the storage means is determined based on a required storage capacity obtained by the delay amount and the second bit length.

9. The image forming apparatus according to claim 8, Wherein,
each of the storage units includes a combination of a plurality of semiconductor memory ICs different in maximum storage capacity, and
the combination of the plurality of semiconductor memory ICs is a combination in which a sum of the maximum storage capacities becomes minimum within a range to satisfy the required storage capacity.

10. The image forming apparatus according to claim 7, wherein,
the first bit length is 8 bits and the second bit length is 6 bits.

11. The image forming apparatus according to claim 9, wherein,
the first bit length is 8 bits and the second bit length is 6 bits.

12. The image forming apparatus according to claim 7, wherein,
the print colors are yellow, magenta, cyan and black.

13. An image forming method for forming a color image by a tandem type image forming apparatus, comprising the steps of:
converting a plurality of first image data having a first bit length and provided for respective print colors into a plurality of second image data having a second bit length smaller than the first bit length in at least one of the print colors;
temporarily storing the second image data for the respective print colors and setting delay amounts different for the respective print colors to the second image data;
exposing a plurality of photoreceptors that are provided for the respective print colors and are arranged at specified intervals; and
moving an image bearing body along the plurality of photoreceptors and superimposing and transferring the print colors onto the image bearing body.

14. The image forming method according to claim 13, Wherein,
the plurality of storage units are set so that the delay amount of the print color corresponding to the photoreceptor positioned at a downstream side in a movement of the image bearing body is larger than the delay amount of the print color corresponding to the photoreceptor positioned at an upstream side, and
a storage capacity of each of the storage units is determined based on a required storage capacity obtained by the delay amount and the second bit length.

15. The image forming method according to claim 14, Wherein,
each of the storage units includes a combination of a plurality of semiconductor memory ICs different in maximum storage capacity, and
the combination of the plurality of semiconductor memory ICs is a combination in which a sum of the maximum storage capacities becomes minimum within a range to satisfy the required storage capacity.

16. The image forming method according to claim 13, wherein,
the first bit length is 8 bits and the second bit length is 6 bits.

17. The image forming method according to claim 15, wherein,
the first bit length is 8 bits and the second bit length is 6 bits.

18. The image forming method according to claim 13, wherein,
the print colors are yellow, magenta, cyan and black.
